(19) United States
(12) Patent Application Publication
(10) Pub. No.: US 2024/0055380 A1
(43) Pub. Date: Feb. 15, 2024

(54) SEMICONDUCTOR DEVICE HAVING A BONDED STRUCTURE AND AN ELECTRONIC SYSTEM INCLUDING THE SAME

(71) Applicant: SAMSUNG ELECTRONICS CO., LTD., Suwon-si (KR)

(72) Inventors: Changbum KIM, Suwon-si (KR); Cheonan Lee, Suwon-si (KR); Sukkang Sung, Suwon-si (KR)

(21) Appl. No.: 18/231,838

(22) Filed: Aug. 9, 2023

(30) Foreign Application Priority Data
Aug. 12, 2022 (KR) 10-2022-0101584

(51) Int. Cl. H01L 23/00; H01L 25/065; H10B 43/35; H10B 41/35

(52) U.S. Cl. CPC H01L 24/08; H01L 25/0657; H10B 43/35; H10B 41/35; H10B 80/00

(57) ABSTRACT

A semiconductor device includes: a first structure including a first substrate and a peripheral circuit disposed on the first substrate; and a second structure including a common source plate and a cell stack disposed on the common source plate and including a plurality of gate electrodes and channel structures, wherein the cell stack includes a plurality of cell blocks including a plurality of main blocks and at least one dummy block disposed at one side of the plurality of main blocks, wherein the common source plate includes a main common source line region and a dummy common source line region, wherein the main common source line region overlaps the plurality of main blocks, and the dummy common source line region is separated from the main common source line region and overlaps the at least one dummy block by being electrically isolated from the at least one dummy block.

### CROSS-REFERENCE TO RELATED APPLICATION

This application claims priority under 35 U.S.C. § 119 to Korean Patent Application No. 10-2022-0101584, filed on Aug. 12, 2022, in the Korean Intellectual Property Office, the disclosure of which is incorporated by reference herein in its entirety.

### TECHNICAL FIELD

The present inventive concept relates to a semiconductor device and an electronic system including the same, and more particularly, to a semiconductor device having a bonded structure and an electronic system including the same.

### DISCUSSION OF THE RELATED ART

Electronic systems having data storage demand a semiconductor device capable of storing a large amount of data. Accordingly, research on a method capable of increasing a data storage capacity of a semiconductor device is being conducted. For example, as one of the methods of increasing a data storage capacity of a semiconductor device, a semiconductor device including three-dimensionally arranged memory cells instead of two-dimensionally arranged memory cells has been under development. In addition, a semiconductor device in a manner of forming a portion of the semiconductor device on a first substrate, forming the other portion of the semiconductor device on a second substrate, and bonding the first substrate to the second substrate has been under development.

### SUMMARY

According to an example embodiment of the present inventive concept, a semiconductor device includes: a first structure including a first substrate, a peripheral circuit disposed on the first substrate, a first insulating structure disposed on the peripheral circuit and the first substrate, and a first bonding pad disposed on the first insulating structure; and a second structure including a common source plate, a cell stack, a second insulating structure, a second bonding pad, and an interconnect structure electrically connecting the cell stack to the second bonding pad, wherein the cell stack is disposed on the common source plate and includes a plurality of gate electrodes and a plurality of channel structures connected to the common source plate by passing through the plurality of gate electrodes, wherein the second insulating structure is disposed on the cell stack and being in contact with the first insulating structure, wherein the second bonding pad is disposed on the second insulating structure and is in contact with the first bonding pad, wherein the cell stack includes a plurality of cell blocks defined between a plurality of stack insulating layers extending in a first horizontal direction by passing through the cell stack, and wherein the plurality of cell blocks includes a plurality of main blocks and at least one dummy block disposed at one side of the plurality of main blocks, wherein the common source plate includes a main common source line region and a dummy common source line region, wherein the main common source line region vertically overlaps the plurality of main blocks, wherein the dummy common source line region is separated from the main common source line region and vertically overlaps the at least one dummy block by being electrically isolated from the at least one dummy block.

According to an example embodiment of the present inventive concept, a semiconductor device includes: a first structure including a first substrate, a peripheral circuit disposed on the first substrate, a first insulating structure disposed on the peripheral circuit and the first substrate, and a first bonding pad disposed on the first insulating structure; and a second structure including a common source plate, a cell stack, a second insulating structure, and a second bonding pad disposed on the second insulating structure and being in contact with the first bonding pad, wherein the cell stack is disposed on the common source plate and includes a plurality of gate electrodes and a plurality of channel structures passing through the plurality of gate electrodes, wherein the second insulating structure is disposed on the cell stack and is in contact with the first insulating structure, wherein the cell stack includes a main block and a dummy block disposed at one side of the main block, wherein the common source plate includes: a main common source line region connected to a first channel structure in the main block among the plurality of channel structures; and a dummy common source line region connected to a second channel structure in the dummy block among the plurality of channel structures and separated from the main common source line region, wherein the dummy common source line region is configured to float when a common source voltage is applied to the main common source line region.

According to an example embodiment of the present inventive concept, an electronic system includes: a main substrate; a semiconductor device disposed on the main substrate; and a controller electrically connected to the semiconductor device on the main substrate, wherein the semiconductor device includes: a first structure including a first substrate, a peripheral circuit disposed on the first substrate, a first insulating structure disposed on the peripheral circuit and the first substrate, and a first bonding pad disposed on the first insulating structure; a second structure including a common source plate, a cell stack, a second insulating structure, a second bonding pad, and an interconnect structure electrically connecting the cell stack to the second bonding pad, wherein the cell stack is disposed on the common source plate and includes a plurality of gate electrodes and a plurality of channel structures connected to the common source plate by passing through the plurality of gate electrodes, wherein the second insulating structure is disposed on the cell stack and is in contact with the first insulating structure, wherein the second bonding pad is disposed on the second insulating structure and is in contact with the first bonding pad, wherein the cell stack includes a plurality of cell blocks defined between a plurality of stack insulating layers extending in a first horizontal direction by passing through the cell stack, and the plurality of cell blocks includes a plurality of main blocks and at least one dummy block disposed at one side of the plurality of main blocks; and a connection structure including an outer insulating layer and an input-output pad, wherein the connection structure covers the common source plate and is disposed on the second structure, and wherein the input-output pad is disposed on the outer insulating layer and is electrically connected to the interconnect structure, wherein at least a portion of the input-output pad vertically overlaps at least a portion of the at least one dummy block, wherein the common source plate includes a main common source line region and a dummy common source line region, wherein the main common source line region vertically overlaps the plurality of main blocks, wherein the dummy common source line region is separated from the main common source line region and vertically overlaps the at least one dummy block by being electrically isolated from the at least one dummy block.

### BRIEF DESCRIPTION OF THE DRAWINGS

The above and other aspects of the present inventive concept will become more apparent by describing in detail embodiments thereof, with reference to the accompanying drawings, in which:

FIG. 1 is a block diagram of a semiconductor device according to an example embodiment of the present inventive concept;

FIG. 2 is a circuit diagram of a memory cell array in a semiconductor device, according to an example embodiment of the present inventive concept;

FIG. 3 is a perspective view illustrating a representative configuration of a semiconductor device according to an example embodiment of the present inventive concept;

FIG. 4 is a top view of the semiconductor device of FIG. 3;

FIG. 5 is a magnified view of part A1 of FIG. 4;

FIG. 6 is a magnified view of part A2 of FIG. 4;

FIG. 7 is a cross-sectional view taken along line B1-B1′ of FIG. 6;

FIG. 8 is a cross-sectional view taken along line B2-B2′ of FIG. 6;

FIGS. 9, 10 and 11 are magnified cross-sectional views illustrating a channel structure according to example embodiments of the present inventive concept;

FIG. 12 is a cross-sectional view illustrating a semiconductor device according to an example embodiment of the present inventive concept;

FIG. 13 is a cross-sectional view illustrating a semiconductor device according to an example embodiment of the present inventive concept;

FIG. 14 is a top view illustrating a semiconductor device according to an example embodiment of the present inventive concept:

FIG. 15 is a top view illustrating a semiconductor device according to an example embodiment of the present inventive concept;

FIG. 16 is a top view illustrating a semiconductor device according to an example embodiment of the present inventive concept;

FIG. 17 is a top view illustrating a semiconductor device according to an example embodiment of the present inventive concept;

FIG. 18 is a magnified view of part A4 of FIG. 17;

FIG. 19 is a top view illustrating a semiconductor device according to an example embodiment of the present inventive concept;

FIG. 20 is a cross-sectional view taken along line B3-B3′ of FIG. 19;

FIG. 21 is a block diagram of an electronic system including a semiconductor device, according to an example embodiment of the present inventive concept;

FIG. 22 is a perspective view schematically illustrating an electronic system including a semiconductor device, according to an example embodiment of the present inventive concept; and

FIG. 23 is a cross-sectional view illustrating a semiconductor package according to an example embodiment of the present inventive concept.

### DETAILED DESCRIPTION OF THE EMBODIMENTS

Hereinafter, embodiments of the present inventive concept are described in detail with reference to the accompanying drawings.

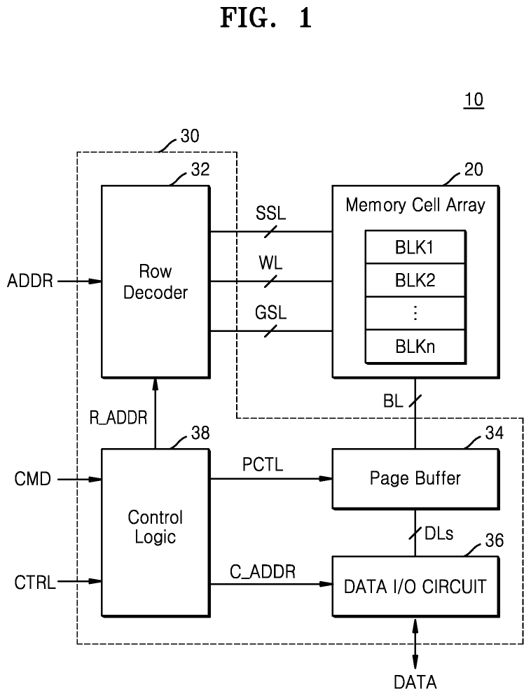

FIG. 1 is a block diagram of a semiconductor device 10 according to an example embodiment of the present inventive concept.

Referring to FIG. 1, the semiconductor device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through bit lines BL, word lines WL, string select lines SSL, and ground select lines GSL.

The peripheral circuit 30 may include a row decoder 32, a page buffer 34, a data input-output circuit 36, and a control logic 38. For example, the peripheral circuit 30 may further include an input-output interface, a column logic, a voltage generator, a pre-decoder, a temperature sensor, a command decoder, an address decoder, an amplification circuit, and the like.

The memory cell array 20 may be connected to the page buffer 34 through the bit lines BL and connected to the row decoder 32 through the word lines WL, the string select lines SSL, and the ground select lines GSL. In the memory cell array 20, each of a plurality of memory cells included in each of the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each of the plurality of NAND strings may include a plurality of memory cells vertically stacked on a substrate and connected to a plurality of word lines WL.

The peripheral circuit 30 may receive an address ADDR, a command CMD, and a control signal CTRL from the outside (e.g., an external device) of the semiconductor device 10 and transmit and receive data DATA to and from a device outside the semiconductor device 10.

The row decoder 32 may select at least one of the plurality of memory cell blocks BLK1, BLK2, . . . , and BLKn in response to the address ADDR from the outside and may select a word line WL, a string select line SSL, and a ground select line GSL of the selected memory cell block. The row decoder 32 may provide, to the word line WL of the selected memory cell block, a voltage for performing a memory operation.

The page buffer 34 may be connected to the memory cell array 20 through the bit lines BL. The page buffer 34 may operate as a write driver during a program operation to apply, to the bit lines BL, a voltage according to the data DATA that is to be stored in the memory cell array 20, and may operate as a sensing amplifier during a read operation to sense the data DATA stored in the memory cell array 20. The page buffer 34 may operate in response to a control signal PCTL provided from the control logic 38.

The data input-output circuit 36 may be connected to the page buffer 34 through data lines DLs. During a program operation, the data input-output circuit 36 may receive the data DATA from a memory controller and provide the data DATA to the page buffer 34 as program data based on a column address C_ADDR provided from the control logic 38. During a read operation, the data input-output circuit 36 may provide the data DATA stored in the page buffer 34 to the memory controller as read data based on the column address C_ADDR provided from the control logic 38.

The data input-output circuit 36 may provide an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input-output circuit 36. The control logic 38 may generate various kinds of internal control signals to be used inside the semiconductor device 10, in response to the control signal CTRL. For example, the control logic 38 may adjust voltage levels to be provided to the word lines WL and the bit lines BL during a memory operation, such as a program operation or an erase operation.

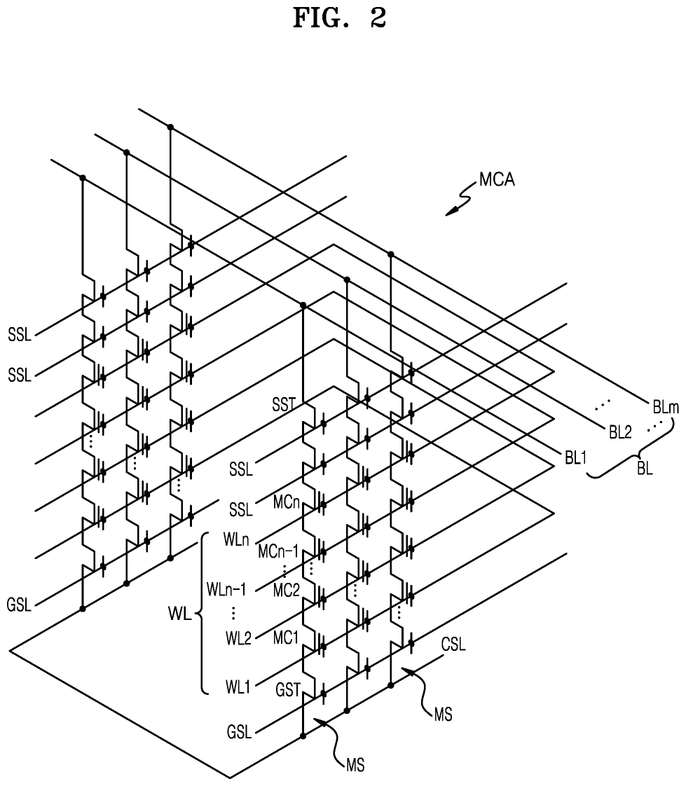

FIG. 2 is a circuit diagram of a memory cell array MCA in the semiconductor device 10, according to an embodiment of the present inventive concept.

Referring to FIG. 2, the memory cell array MCA may include a plurality of memory cell strings MS. The memory cell array MCA may include a plurality of bit lines BL (BL1, BL2, . . . , and BLm), a plurality of word lines WL (WL1, WL2, . . . , WLn−1, and WLn), at least one string select line SSL, at least one ground select line GSL, and a common source line CSL. The plurality of memory cell strings MS may be formed between the plurality of bit lines BL (BL1, BL2, . . . , and BLm) and the common source line CSL. Although FIG. 2 shows that each of the plurality of memory cell strings MS includes two string select lines SSL, the present inventive concept is not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn−1, and MCn. A drain region of the string select transistor SST may be connected to a bit line BL (BL1, BL2, . . . , or BLm), and a source region of the ground select transistor GST may be connected to the common source line CSL. The common source line CSL may be a region to which source regions of a plurality of ground select transistors GST are commonly connected.

The string select transistor SST may be connected to a string select line SSL, and the ground select transistor GST may be connected to a ground select line GSL. The plurality of memory cell transistors MC1, MC2, . . . , MCn−1, and MCn may be connected to the plurality of word lines WL (WL1, WL2, . . . , WLn−1, and WLn), respectively.

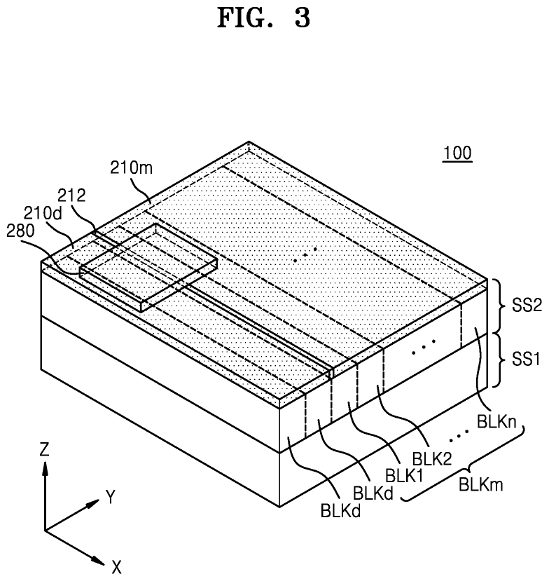

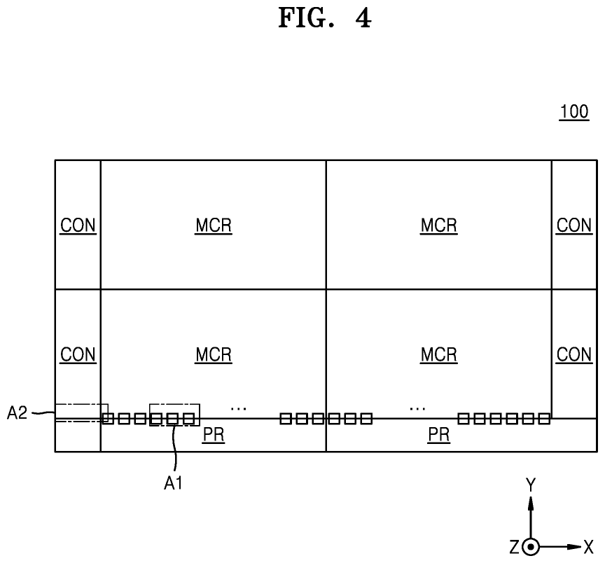

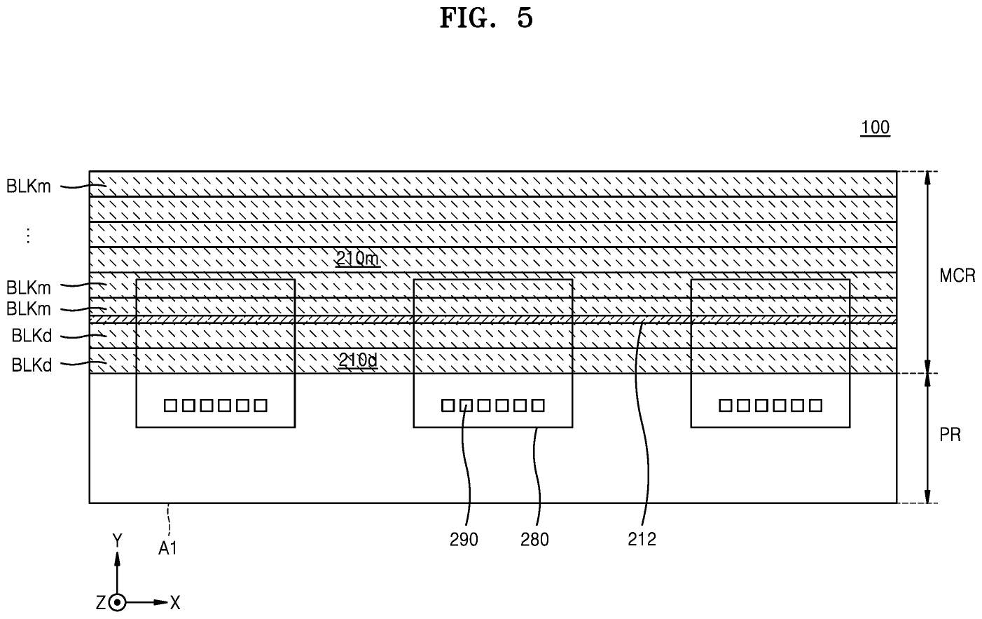

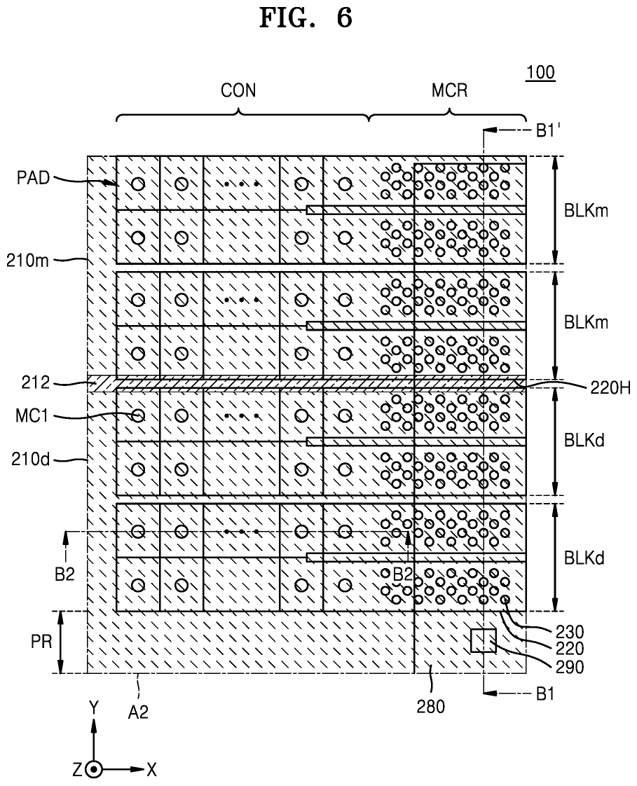

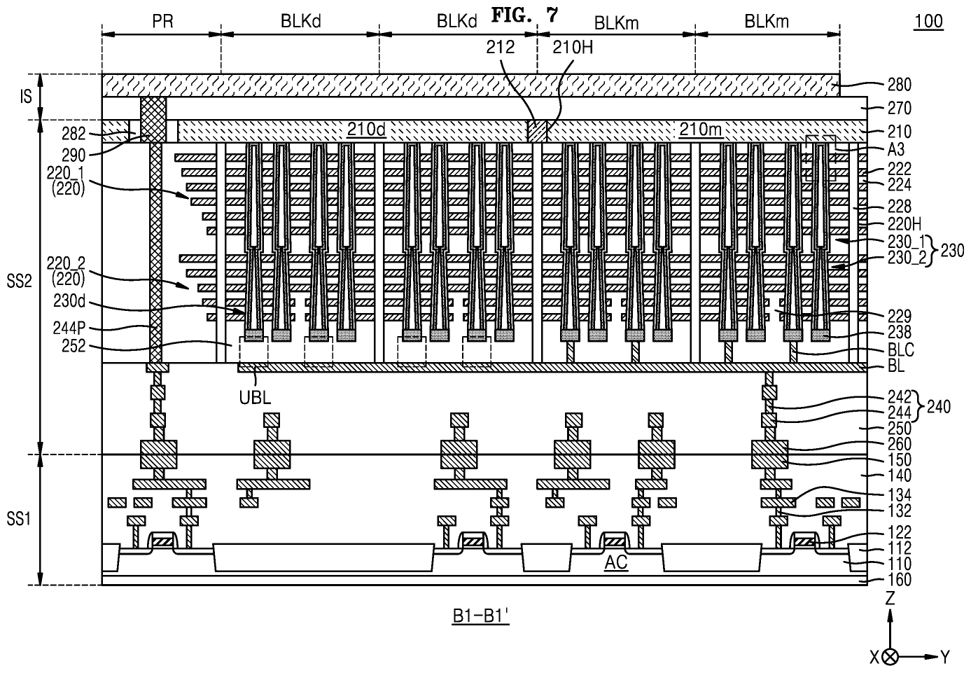

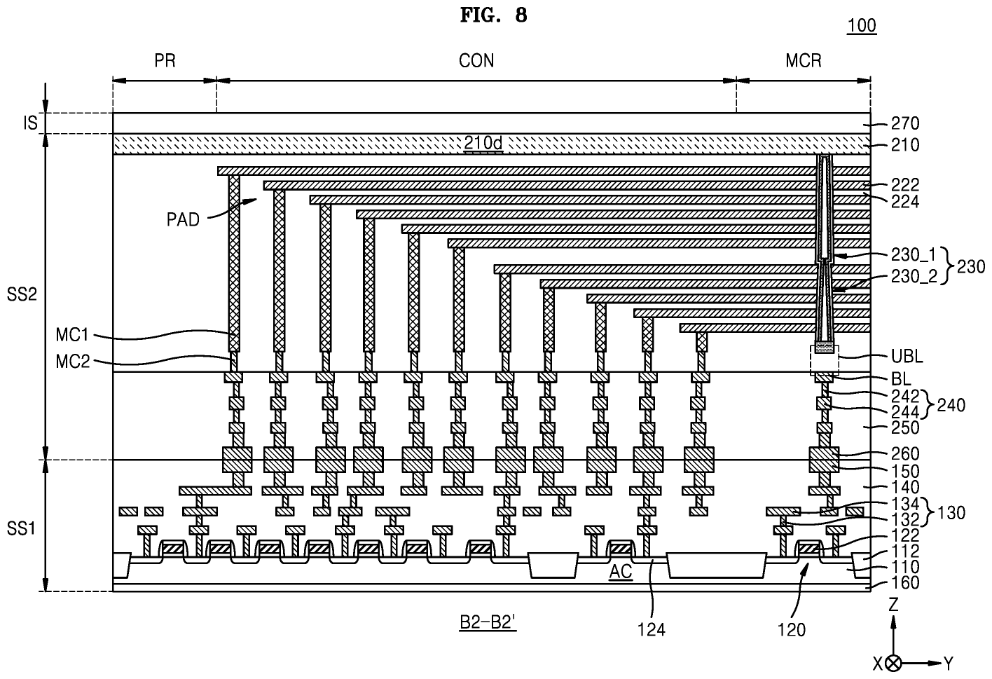

FIGS. 3 to 8 illustrate a semiconductor device 100 according to embodiments of the present inventive concept. Particularly, FIG. 3 is a perspective view illustrating a representative configuration of the semiconductor device 100 according to an example embodiment of the present inventive concept and FIG. 4 is a top view illustrating the semiconductor device 100 of FIG. 3. FIG. 5 is a magnified view of part A1 of FIG. 4, FIG. 6 is a magnified view of part A2 of FIG. 4, FIG. 7 is a cross-sectional view taken along line B1-B1′ of FIG. 6, and FIG. 8 is a cross-sectional view taken along line B2-B2′ of FIG. 6.

Referring to FIGS. 3 to 8, the semiconductor device 100 may include a first structure SS1 and a second structure SS2 that are bonded to each other in a vertical direction Z. The semiconductor device 100 may further include a connection structure IS that is disposed on the second structure SS2. The first structure SS1 may include the peripheral circuit 30 described with reference to FIG. 1, and the second structure SS2 may include the memory cell array 20 described with reference to FIG. 1. The connection structure IS may include an input-output terminal for an electrical connection between the peripheral circuit 30 and an external device. In a top view, the semiconductor device 100 may include a memory cell region MCR, a connection region CON, and a pad region PR.

The second structure SS2 may include a plurality of cell blocks, and the plurality of cell blocks may include a plurality of main blocks BLKm and at least one dummy block BLKd. The plurality of main blocks BLKm may include the plurality of memory cell blocks BLK1, BLK2, . . . , and BLKn described with reference to FIG. 1. Each of the plurality of memory cell blocks BLK1, BLK2, . . . , and BLKn may include three-dimensionally arranged memory cells.

The first structure SS1 may include a first substrate 110, a peripheral circuit 120 that is disposed on the first substrate 110, a first interconnect structure 130 electrically connected to the peripheral circuit 120, a first insulating structure 140 that is disposed on the first substrate 110 and the peripheral circuit 120, and a first bonding pad 150 that is disposed on the first insulating structure 140.

The first substrate 110 may include a semiconductor material, e.g., a Group IV semiconductor, a Group III-V compound semiconductor, or a Group II-VI oxide semiconductor. For example, the Group IV semiconductor may include silicon (Si), germanium (Ge), or SiGe. The first substrate 110 may be provided as a bulk wafer or an epitaxial layer. In an example embodiment of the present inventive concept, the first substrate 110 may include a silicon-on-insulator (SOI) substrate or a germanium-on-insulator (GeOI) substrate. The first substrate 110 may have an active region AC defined by a device isolation layer 112, and a plurality of peripheral circuits 120 may be formed on the active region AC. Each of the plurality of peripheral circuits 120 may include a peripheral circuit gate 122 and a source/drain regions 124, which are disposed in portions of the first substrate 110 at both sides of the peripheral circuit gate 122.

The first interconnect structure 130 may include a plurality of peripheral circuit contacts 132 and a plurality of peripheral circuit wiring layers 134. The first insulating structure 140 may cover the peripheral circuit 120 and the first interconnect structure 130 on the first substrate 110. The first bonding pad 150 may be on the first insulating structure 140 and may be electrically connected to the peripheral circuit 120 and/or the first substrate 110 via the first interconnect structure 130. The first bonding pad 150 may have an upper surface substantially coplanar with an upper surface of the first insulating structure 140.

In some example embodiments of the present inventive concept, the first insulating structure 140 may include an insulating material, such as silicon oxide, silicon nitride, a low-k material, or a combination thereof. The low-k material is a material having a lower dielectric constant than silicon oxide and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. The first bonding pad 150 may include a conductive material, such as copper (Cu), gold (Au), silver (Ag), aluminum (Al), tungsten (W), titanium (Ti), tantalum (Ta), or a combination thereof.

The second structure SS2 may include a common source plate 210, a cell stack 220 on the common source plate 210, a second interconnect structure 240, which is electrically connected to the cell stack 220 and includes a plurality of contacts 242, and a plurality of wiring layers 244, a second insulating structure 250 covering the cell stack 220 and the second interconnect structure 240, and a second bonding pad 260 that is disposed on the second insulating structure 250.

The cell stack 220 may include a plurality of gate electrodes 222 and a plurality of insulating layers 224 alternately disposed on the common source plate 210, and the cell stack 220 may further include a plurality of channel structures 230 extending in the vertical direction Z by passing through the plurality of gate electrodes 222 and the plurality of insulating layers 224. The cell stack 220 may include a plurality of cell blocks provided between a plurality of stack insulating layers 228 extending in a first horizontal direction X by passing through the cell stack 220, and the plurality of cell blocks may include the plurality of main blocks BLKm and the at least one dummy block BLKd. For example, the at least one dummy block BLKd may be at both sides of the plurality of main blocks BLKm, and the at least one dummy block BLKd may include a plurality of dummy memory cells formed to have the same or similar structure as or to that of the plurality of main blocks BLKm but not to function as a memory cell.

The common source plate 210 may function as a source region configured to supply a current to memory cells that are formed in the second structure SS2. In some example embodiments of the present inventive concept, the common source plate 210 may include at least one of, for example, Si, Ge, SiGe, gallium arsenide (GaAs), indium gallium arsenide (InGaAs), aluminum gallium arsenide (AlGaAs), and a mixture thereof. In addition, the common source plate 210 may include a semiconductor doped with n-type impurities. In addition, the common source plate 210 may have a crystal structure including at least one of a monocrystalline structure, an amorphous structure, and a polycrystalline structure. In some example embodiments of the present inventive concept, the common source plate 210 may include polysilicon doped with n-type impurities.

The common source plate 210 may include a main common source line region 210m and a dummy common source line region 210d. The dummy common source line region 210d may be separated from the main common source line region 210m in a second horizontal direction Y and may be electrically isolated from the main common source line region 210m. For example, the dummy common source line region 210d may float when a common source voltage is applied to the main common source line region 210m.

The main common source line region 210m may vertically overlap the plurality of main blocks BLKm, and channel structures 230 included in the plurality of main blocks BLKm may be in contact with the main common source line region 210m by passing through the plurality of gate electrodes 222 and the plurality of insulating layers 224.

The dummy common source line region 210d may vertically overlap the at least one dummy block BLKd, and channel structures 230 included in the at least one dummy block BLKd may be in contact with the dummy common source line region 210d by passing through the plurality of gate electrodes 222 and the plurality of insulating layers 224.

The common source plate 210 may include an opening 210H, and a common source isolation insulating layer 212 may be disposed in the opening 210H. The main common source line region 210m may be separated and electrically isolated from the dummy common source line region 210d by the common source isolation insulating layer 212. In some example embodiments of the present inventive concept, the common source isolation insulating layer 212 may extend in the first horizontal direction X along the length of the cell stack 220 in the first horizontal direction X, and for example, a length of the common source isolation insulating layer 212 in the first horizontal direction X may be greater than or equal to the length of the cell stack 220 in the first horizontal direction X. For example, the common source isolation insulating layer 212 may extend in the first horizontal direction X along the entire length of the cell stack 220 in the first horizontal direction X.

In some example embodiments of the present inventive concept, the common source isolation insulating layer 212 may include silicon oxide, silicon nitride, silicon oxynitride (SiON), silicon oxide carbon nitride (SiOCN), silicon carbon nitride (SiCN), or a combination thereof. For example, the opening 210H may be formed by removing a portion of the common source plate 210, and the common source isolation insulating layer 212 may be formed by filling the opening 210H with an insulating material. The common source isolation insulating layer 212 may include an upper surface, which is close to the connection structure IS, and a lower surface, which is close to the cell stack 220. In some example embodiments of the present inventive concept, the common source isolation insulating layer 212 may have a side wall inclined so that a width of the upper surface of the common source isolation insulating layer 212 is greater than a width of the lower surface of the common source isolation insulating layer 212. In some example embodiments of the present inventive concept, the common source isolation insulating layer 212 may have a side wall inclined so that the width of the lower surface of the common source isolation insulating layer 212 is greater than the width of the upper surface of the common source isolation insulating layer 212.

As shown in FIG. 5, because the common source isolation insulating layer 212 has a rectangular shape or a straight line shape extending in the first horizontal direction X, in a top view, the dummy common source line region 210d may have a rectangular horizontal cross-section, and the main common source line region 210m may have a rectangular horizontal cross-section.

In some example embodiments of the present inventive concept, the plurality of gate electrodes 222 may correspond to at least one ground select line GSL, the plurality of word lines WL (WL1, WL2, . . . , WLn−1, and WLn), and at least one string select line SSL constituting a memory cell string MS (see FIG. 2). For example, a gate electrode 222 closest to the common source plate 210 may function as a ground select line GSL, and two gate electrodes 222 farthest from the common source plate 210 may function as string select lines SSL. The other gate electrodes 222 may function as the plurality of word lines WL. Accordingly, a memory cell string MS having a ground select transistor GST, two string select transistors SST, and memory cell transistors MC1, MC2, . . . , MCn−1, and MCn connected in series may be provided.

In some example embodiments of the present inventive concept, at least one of the plurality of gate electrodes 222 may function as a dummy word line. For example, at least one additional gate electrode 222 may be between the gate electrode 222 functioning as the ground select line GSL and the common source plate 210, at least one additional gate electrode 222 may be between the gate electrode 222 functioning as the ground select line GSL and a gate electrode 222 functioning as a word line WL, or at least one additional gate electrode 222 may be between a gate electrode 222 functioning as a word line WL and a gate electrode 222 functioning as a string select line SSL.

The plurality of channel structures 230 may extend in the vertical direction Z by passing through the plurality of gate electrodes 222 and the plurality of insulating layers 224 from the upper surface of the common source plate 210 on the memory cell region MCR. The plurality of channel structures 230 may be separated from each other by a certain interval from each other in the first horizontal direction X, the second horizontal direction Y, and a third horizontal direction (e.g., a diagonal direction). The plurality of channel structures 230 may be arranged in a zigzag shape, a staggered shape or an alternating arrangement.

In some example embodiments of the present inventive concept, the cell stack 220 may have a double stack structure, for example, the cell stack 220 may include a first sub-stack 220_1 and a second sub-stack 220_2 stacked on each other in the vertical direction Z, and the first sub-stack 220_1 may be closer to the common source plate 210 than the second sub-stack 220_2. The plurality of channel structures 230 may include a first channel part 230_1, which passes through the first sub-stack 220_1 of the cell stack 220, and a second channel part 230_2, which is connected to the first channel part 230_1 by passing through the second sub-stack 220_2 of the cell stack 220 at a position where the second channel part 230_2 vertically overlaps the first channel part 230_1. In some example embodiments of the present inventive concept, the first sub-stack 220_1 of the cell stack 220 may be formed first, and then, the first channel part 230_1 passing through the first sub-stack 220_1 may be formed. Then, the second sub-stack 220_2 of the cell stack 220 may be formed, and then the second channel part 230_2 passing through the second sub-stack 220_2 may be formed. However, the present inventive concept is not limited thereto, and the cell stack 220 may have a single stack structure or a structure in which three or more sub-stacks are stacked.

A stack insulating layer 228 may be in a plurality of stack isolation openings 220H extending in the first horizontal direction X by passing through the cell stack 220, and the plurality of gate electrodes 222 between a pair of stack isolation openings 220H may constitute a cell block. The stack insulating layer 228 may include, for example, silicon oxide, silicon nitride, SiON, SiOCN, SiCN, or a combination thereof. The plurality of bit lines BL may extend in the second horizontal direction Y and be separated from each other in the first horizontal direction X, and each bit line BL may be electrically connected to a channel structure 230 by a bit line contact BLC.

In some example embodiments of the present inventive concept, a channel structure 230 included in the plurality of main blocks BLKm may be electrically connected to a bit line BL by a bit line contact BLC, whereas no bit line contact BLC may be formed on a channel structure 230d included in the at least one dummy block BLKd, and accordingly, the channel structure 230d included in the at least one dummy block BLKd may be electrically isolated from the bit line BL.

As shown in FIG. 7, the channel structure 230d included in the at least one dummy block BLKd may be covered by a portion of the second insulating structure 250, e.g., an upper insulating layer 252, and this portion may be referred to as a bit line non-connection portion UBL. A first end portion of the channel structure 230d included in the at least one dummy block BLKd may be electrically connected to the dummy common source line region 210d, and a second end portion opposite to the first end portion may be covered by the bit line non-connection portion UBL and thus electrically isolated from the bit line BL. Therefore, the at least one dummy block BLKd may be electrically isolated from the plurality of main blocks BLKm.

As shown in FIG. 7, within one cell block in the memory cell region MCR, two gate electrodes 222 farthest from the common source plate 210 may be divided into two parts by a string division opening in a top view. For example, the string division opening may divide the plurality of gate electrodes 222 corresponding to one cell block into two parts in the second horizontal direction Y, and a string isolation insulating layer 229 may be in the string division opening.

On the connection region CON, the plurality of gate electrodes 222 may constitute a pad part PAD. In the connection region CON, the plurality of gate electrodes 222 may extend to have a length gradually decreasing in the first horizontal direction X or the second horizontal direction Y as distance away from the upper surface of the common source plate 210 increases. For example, the plurality of gate electrodes 222 may form a staircase shape. The pad part PAD may indicate staircase-shaped parts of the plurality of gate electrodes 222. In some example embodiments of the present inventive concept, the pad part PAD may have a staircase shape in both the first horizontal direction X and the second horizontal direction Y. In some example embodiments of the present inventive concept, the pad part PAD may have a staircase shape in the first horizontal direction X only. Although FIG. 8 shows that the plurality of gate electrodes 222, which constitute the pad part PAD, are formed with the same thickness as that of the plurality of gate electrodes 222 in the memory cell region MCR, in some example embodiments of the present inventive concept, the plurality of gate electrodes 222 constituting the pad part PAD may have a greater thickness than the plurality of gate electrodes 222 in the memory cell region MCR. For example, a portion of a gate electrode 222 constituting the pad part PAD may be thicker than another portion of the gate electrode 222 in the memory cell region MCR.

For example, a plurality of dummy channel structures, which extend in the vertical direction Z from the upper surface of the common source plate 210 by passing through the plurality of gate electrodes 222 and the plurality of insulating layers 224, may be formed in the connection region CON. The dummy channel structure may be formed to prevent leaning, bending, or the like of the gate electrode 222 and ensure the structural stability of the gate electrode 222 in a manufacturing process of the semiconductor device 100. In some example embodiments of the present inventive concept, the dummy channel structure may have the same height and shape as the channel structure 230 and may include an insulating material. In some example embodiments of the present inventive concept, the plurality of dummy channel structures may have a similar structure and shape as that of the plurality of channel structures 230.

The second insulating structure 250 may be on the plurality of gate electrodes 222 constituting the pad part PAD. The second insulating structure 250 may include a plurality of insulating layers, and each of the plurality of insulating layers may cover the pad part PAD, the cell stack 220, the bit line contact BLC, and the second interconnect structure 240.

On the connection region CON, a cell contact MC1 that is connected to the gate electrode 222 by passing through the second insulating structure 250 may be disposed. A cell contact plug MC2 at the same vertical level as the bit line contact BLC may be on the cell contact MC1 (or below the cell contact MC1 as shown in FIG. 7), and the cell contact plug MC2 may be connected to the second interconnect structure 240.

By making the second insulating structure 250 be in contact with the first insulating structure 140 and making the second bonding pad 260 be in contact with the first bonding pad 150 corresponding thereto, the second structure SS2 may be bonded to the first structure SS1. For example, the first structure SS1 and the second structure SS2 may be bonded to each other by metal-oxide hybrid bonding, and accordingly, the second interconnect structure 240 included in the second structure SS2 may be electrically connected to the peripheral circuit 120 included in the first structure SS1.

The connection structure IS may be on the second structure SS2, and the connection structure IS may include an outer insulating layer 270, which is disposed on the common source plate 210, an input-output pad 280, which is disposed on the outer insulating layer 270, and a connection via 290 connecting the input-output pad 280 to a peripheral contact plug 244P by passing through the outer insulating layer 270. In some example embodiments of the present inventive concept, the connection via 290 may vertically overlap the dummy common source line region 210d, and in this case, an insulating layer 282 may be formed on a side wall of the connection via 290 to electrically isolate the connection via 290 from the dummy common source line region 210d.

As shown in FIG. 5, the input-output pad 280 may vertically overlap the memory cell region MCR at an edge of the memory cell region MCR, e.g., vertically overlap the at least one dummy block BLKd and the plurality of main blocks BLKm. At least a portion of the input-output pad 280 may vertically overlap the at least one dummy block BLKd, and the at least one dummy block BLKd may be on the dummy common source line region 210d electrically isolated from the main common source line region 210m. Therefore, it may be configured that the dummy common source line region 210d floats even when the common source voltage is applied to the main common source line region 210m, and the plurality of main blocks BLKm operate, and accordingly, an input-output capacitance by the input-output pad 280 may be reduced, thereby reducing common source line noise or increasing input-output performance.

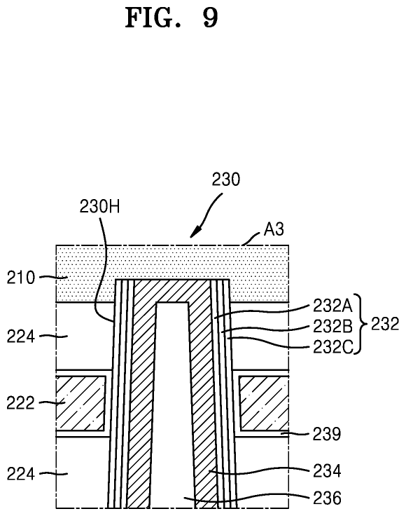

FIGS. 9 to 11 are magnified cross-sectional views illustrating the channel structure 230 according to example embodiments of the present inventive concept. FIGS. 9 to 11 are magnified views of a part corresponding to part A3 of FIG. 7.

Referring to FIG. 9, each of the plurality of channel structures 230 may be in a channel hole 230H on the memory cell region MCR (see FIG. 6). Each of the plurality of channel structures 230 may include a gate insulating layer 232, a channel layer 234, a buried insulating layer 236, and a conductive plug. The gate insulating layer 232 and the channel layer 234 may be sequentially disposed on a side wall of the channel hole 230H. For example, the gate insulating layer 232 may be conformally formed on the side wall of the channel hole 230H, and the channel layer 234 may be conformally formed on the side wall and a bottom portion of the channel hole 230H. The channel layer 234 may be disposed on the upper surface of the common source plate 210 at the bottom portion of the channel hole 230H. For example, the channel layer 234 may be in contact with the upper surface of the common source plate 210 at the bottom portion of the channel hole 230H. The buried insulating layer 236 filling a residual space of the channel hole 230H may be disposed on the channel layer 234. The conductive plug being in contact with the channel layer 234 and covering the entrance of the channel hole 230H may be at an upper side of the channel hole 230H (e.g., in a portion of the channel hole 230H that is closer to the first structure SS1). In some example embodiments of the present inventive concept, the buried insulating layer 236 may be omitted, and the channel layer 234 may be formed in a pillar shape filling the residual space of the channel hole 230H.

The gate electrode 222 may include a metal, such as W, nickel (Ni), cobalt (Co), or Ta, a conductive metal nitride, such as titanium nitride, tantalum nitride, or tungsten nitride, metal silicide, such as tungsten silicide, nickel silicide, cobalt silicide, or tantalum silicide, doped polysilicon, or a combination thereof. A dielectric liner 239 may be between the gate electrode 222 and the insulating layer 224, and the dielectric liner 239 may include a high-k material, such as aluminum oxide.

The gate insulating layer 232 may have a structure sequentially including a tunneling dielectric layer 232A, a charge storage layer 232B, and a blocking dielectric layer 232C disposed on an outer wall of the channel layer 234. Relative thicknesses of the tunneling dielectric layer 232A, the charge storage layer 232B, and the blocking dielectric layer 232C constituting the gate insulating layer 232 are not limited to the thicknesses shown in FIG. 9 and may be variously modified.

The tunneling dielectric layer 232A may include, for example, silicon oxide, hafnium oxide, aluminum oxide, zirconium oxide, tantalum oxide, or the like. The charge storage layer 232B is a region in which electrons having passed through the tunneling dielectric layer 232A from the channel layer 234 may be stored, and may include, for example, silicon nitride, boron nitride, silicon boron nitride, or impurity-doped polysilicon. The blocking dielectric layer 232C may include, for example, silicon oxide, silicon nitride, or metal oxide having a greater dielectric constant than that of the silicon oxide. The metal oxide may include hafnium oxide, aluminum oxide, zirconium oxide, tantalum oxide, or a combination thereof.

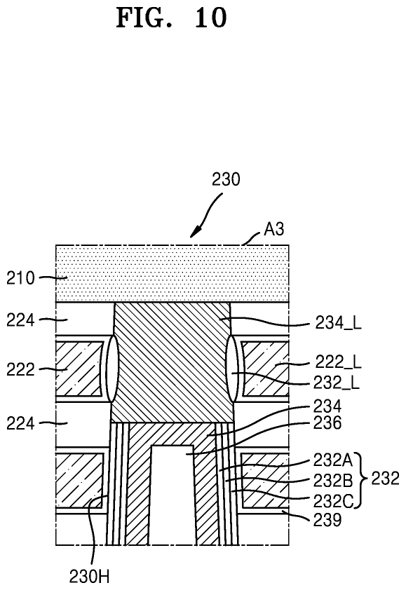

Referring to FIG. 10, the channel structure 230 may further include a contact semiconductor layer 234_L and a bottom insulating layer 232_L at the bottom portion of the channel hole 230H (herein, the bottom portion indicates a first end portion of the channel hole 230H adjacent to the common source plate 210). The channel layer 234 might not be in direct contact with the common source plate 210, and the channel layer 234 may be electrically connected to the common source plate 210 via the contact semiconductor layer 234_L. In some example embodiments of the present inventive concept, the contact semiconductor layer 234_L may include a silicon layer formed by a selective epitaxy growth (SEG) process using the common source plate 210 at the bottom portion of the channel hole 230H as a seed layer.

The bottom insulating layer 232_L may be between the contact semiconductor layer 234_L and a lowermost gate electrode 222_L that is most adjacent to the common source plate 210. In some example embodiments of the present inventive concept, the bottom insulating layer 232_L may include silicon oxide, and for example, the bottom insulating layer 232_L may be formed by performing an oxidation process on a portion of a side wall of the contact semiconductor layer 234_L.

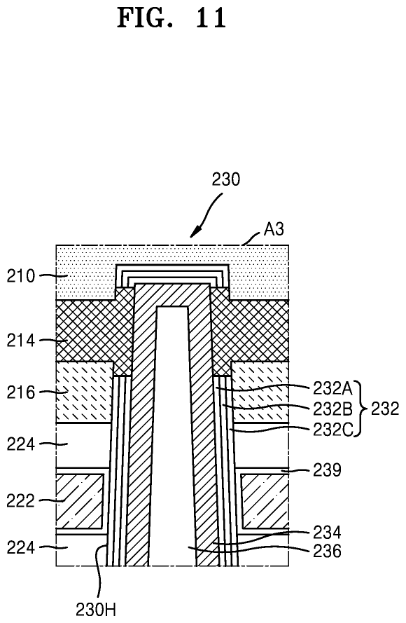

Referring to FIG. 11, the channel structure 230 may have a structure electrically connected to a horizontal semiconductor layer 214 via a side wall of the channel layer 234 instead of being electrically connected to the common source plate 210. For example, the horizontal semiconductor layer 214 and the support layer 216 may be sequentially stacked on the upper surface of the common source plate 210, and the cell stack 220 (see FIG. 7) including the insulating layer 224 and the gate electrode 222 may be on the support layer 216.

In some example embodiments of the present inventive concept, the horizontal semiconductor layer 214 may include polysilicon doped with impurities or without doped with impurities. The horizontal semiconductor layer 214 may function as a portion of a common source region connecting the common source plate 210 to the channel layer 234. For example, the support layer 216 may include doped or undoped polysilicon. The support layer 216 may prevent a mold stack from collapsing or falling in a process of removing a sacrificial material layer for forming the horizontal semiconductor layer 214.

The gate insulating layer 232 may be on an inner wall and the bottom portion of the channel hole 230H. A bottom surface of the channel layer 234 may be on the gate insulating layer 232 so as not to be in direct contact with the common source plate 210, and a side wall of a bottom portion of the channel layer 234 may be at least partially surrounded by the horizontal semiconductor layer 214.

FIGS. 9 to 11 schematically show the channel structure 230 having representative structures employable in example embodiments of the present inventive concept, and it would be understood that the channel structure 230 in some example embodiments of the present inventive concept may have different structures from the structures described with reference to FIGS. 9 to 11.

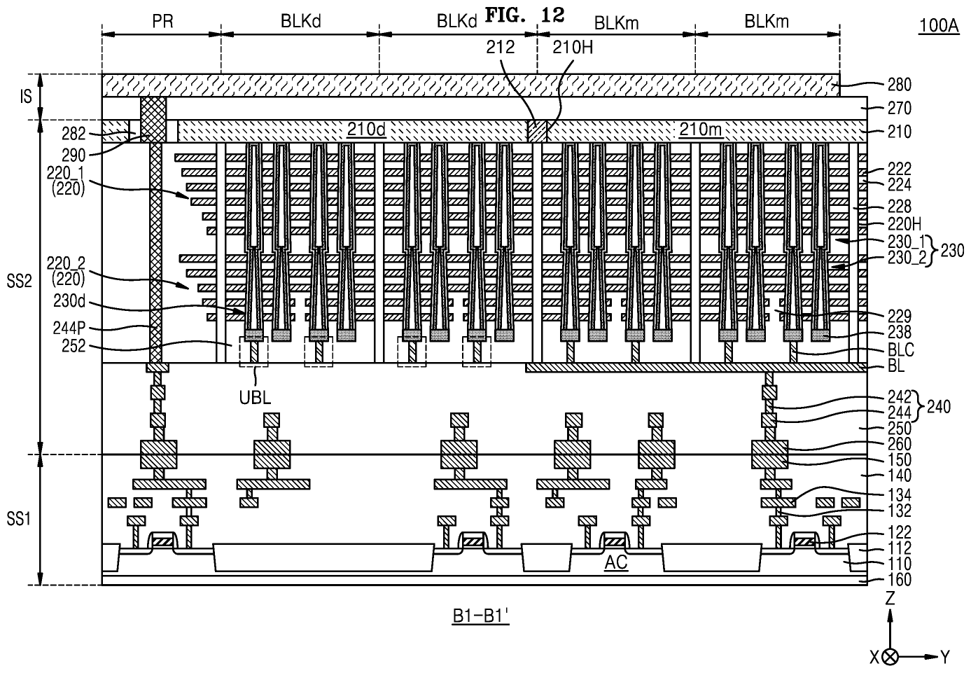

FIG. 12 is a cross-sectional view illustrating a semiconductor device 100A according to an example embodiment of the present inventive concept. FIG. 12 is a cross-sectional view corresponding to the cross-section taken along line B1-B1′ of FIG. 6.

Referring to FIG. 12, the channel structure 230d included in the at least one dummy block BLKd might not be electrically connected to the bit line BL. The bit line BL may vertically overlap the plurality of main blocks BLKm and might not vertically overlap the at least one dummy block BLKd, and accordingly, the bit line contact BLC that is on the channel structure 230d, which is included in the at least one dummy block BLKd, might not be connected to a corresponding bit line BL. For example, the bit line contact BLC that is on the channel structure 230d, which is included in the at least one dummy block BLKd, may be covered by a portion of the second insulating structure 250, and this portion of the second insulating structure 250 may be referred to as the bit line non-connection portion UBL.

The first end portion of the channel structure 230d included in the at least one dummy block BLKd may be electrically connected to the dummy common source line region 210d, and the bit line contact BLC connected to the second end portion opposite to the first end portion may be covered by the bit line non-connection portion UBL and thus might not be electrically connected to the bit line BL. Therefore, the at least one dummy block BLKd may be electrically isolated from the plurality of main blocks BLKm.

According to the embodiment described above, it may be configured that the dummy common source line region 210d floats even when the common source voltage is applied to the main common source line region 210m, and the plurality of main blocks BLKm operate, and accordingly, the input-output capacitance by the input-output pad 280 may be reduced, thereby reducing the common source line noise or increasing the input-output performance.

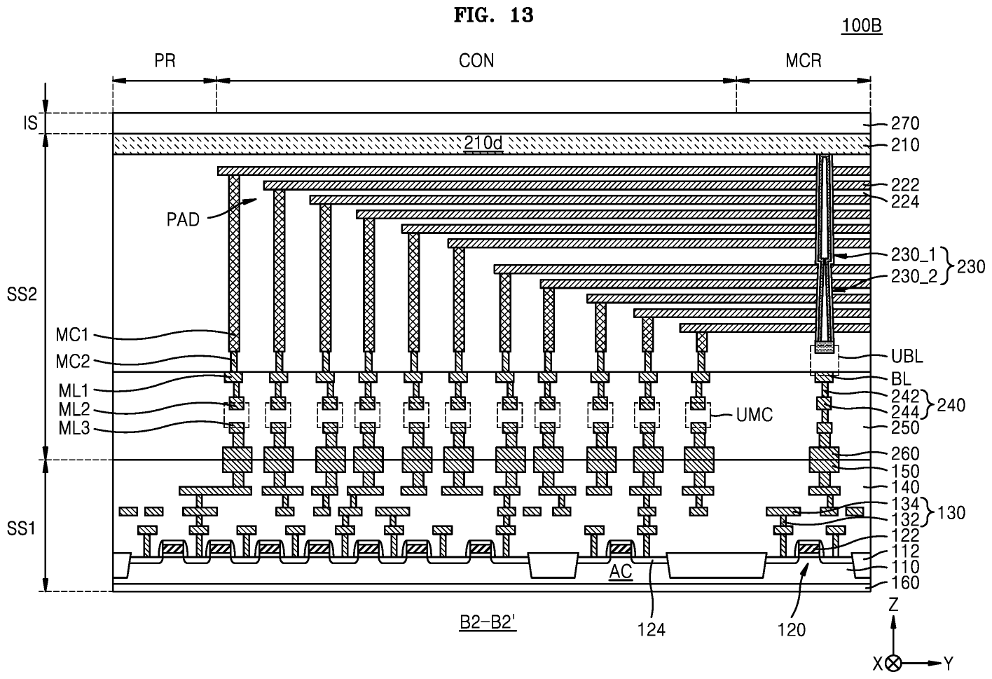

FIG. 13 is a cross-sectional view illustrating a semiconductor device 100B according to an example embodiment of the present inventive concept. FIG. 13 is a cross-sectional view corresponding to the cross-section taken along line B2-B2′ of FIG. 6.

Referring to FIG. 13, it may be configured that the dummy common source line region 210d floats, and the plurality of gate electrodes 222 of the at least one dummy block BLKd float while the common source voltage is applied to the main common source line region 210m, and a gate voltage (e.g., a word line voltage, a ground select line voltage, and a string select line voltage) is applied to the plurality of gate electrodes 222 of the plurality of main blocks BLKm. The channel structure 230d included in the at least one dummy block BLKd might not be electrically connected to the bit line BL, and the plurality of gate electrodes 222 at least partially surrounding the channel structure 230d might not be electrically connected to the peripheral circuit 120 included in the first structure SS1. For example, the pad part PAD included in one dummy block BLKd might not be connected to the second bonding pad 260 because a portion of the second interconnect structure 240 is omitted, and the omitted portion of the second interconnect structure 240 may be referred to as a cell contact non-connection portion UMC.

In some example embodiments of the present inventive concept, a contact 242 between two wiring layers 244, of the wiring layers 244, most adjacent to the second bonding pad 260 may be omitted. For example, when the second interconnect structure 240 includes first to third wiring layers ML1, ML2, and ML3 having different vertical distances from an end portion of the channel structure 230d, no contact 242 may be formed between the second wiring layer ML2 and the third wiring layer ML3, and thus, the second wiring layer ML2 might not be electrically connected to the third wiring layer ML3.

In some example embodiments of the present inventive concept, unlike shown in FIG. 13, the plurality of gate electrodes 222 surrounding the channel structure 230d included in the at least one dummy block BLKd might not be electrically connected to the peripheral circuit 120 included in the first structure SS1 because any one of the first to third wiring layers ML1, ML2, and ML3 or any one of contacts 242 between the first to third wiring layers ML1, ML2, and ML3 may be omitted.

In some example embodiments of the present inventive concept, unlike shown in FIG. 13, the plurality of gate electrodes 222 surrounding the channel structure 230d included in the at least one dummy block BLKd might not be electrically connected to the peripheral circuit 120 included in the first structure SS1 because either the cell contact MC1 or the cell contact plug MC2 is omitted.

In some example embodiments of the present inventive concept, unlike shown in FIG. 13, the plurality of gate electrodes 222 of the at least one dummy block BLKd may be electrically connected to the peripheral circuit 120 included in the first structure SS1 without forming the cell contact non-connection portion UMC (for example, a portion of the second interconnect structure 240 connected to the plurality of gate electrodes 222 of the at least one dummy block BLKd might not be omitted). In this case, it may be configured that the channel structure 230d of the at least one dummy block BLKd floats by applying a dummy gate voltage (e.g., a dummy word line voltage, a dummy ground select line voltage, and a dummy string select line voltage), which is different from the gate voltage, to the plurality of gate electrodes 222 of the at least one dummy block BLKd while the gate voltage (e.g., the word line voltage, the ground select line voltage, and the string select line voltage) is applied to the plurality of gate electrodes 222 of the plurality of main blocks BLKm.

According to the embodiment described above, it may be configured that the dummy common source line region 210d floats even when the common source voltage is applied to the main common source line region 210m, and the plurality of main blocks BLKm operate. Accordingly, the input-output capacitance by the input-output pad 280 may be reduced, thereby reducing the common source line noise or increasing the input-output performance.

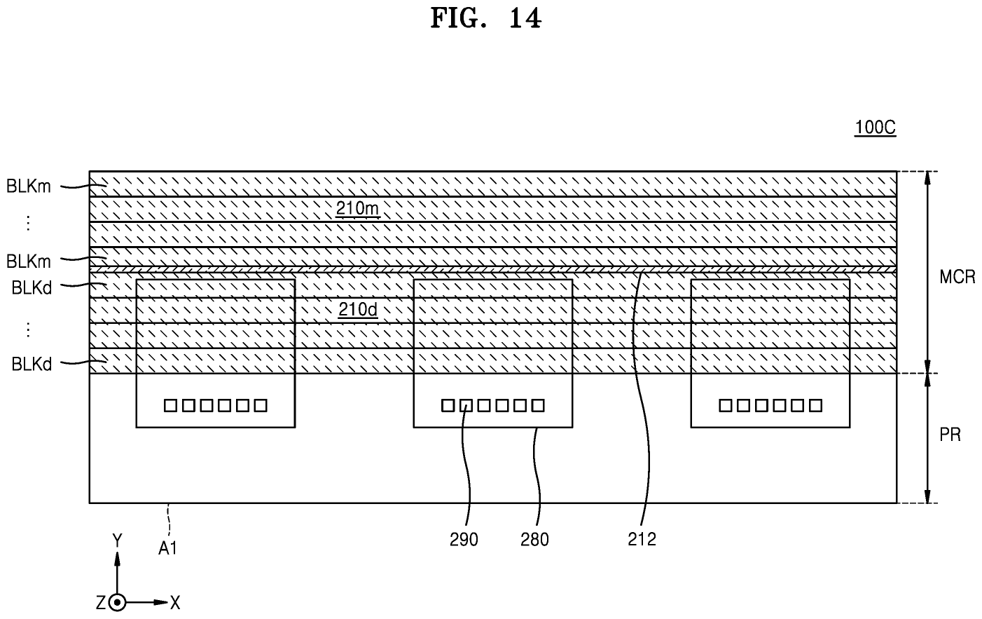

FIG. 14 is a top view illustrating a semiconductor device 100C according to an example embodiment of the present inventive concept.

Referring to FIG. 14, in a top view, a plurality of dummy blocks BLKd may be at one side of the plurality of main blocks BLKm, and the region of the input-output pad 280 may vertically overlap the plurality of dummy blocks BLKd. The common source isolation insulating layer 212 may extend in the first horizontal direction X between the plurality of dummy blocks BLKd and the plurality of main blocks BLKm, and accordingly, the region of the input-output pad 280 may be on the dummy common source line region 210d.

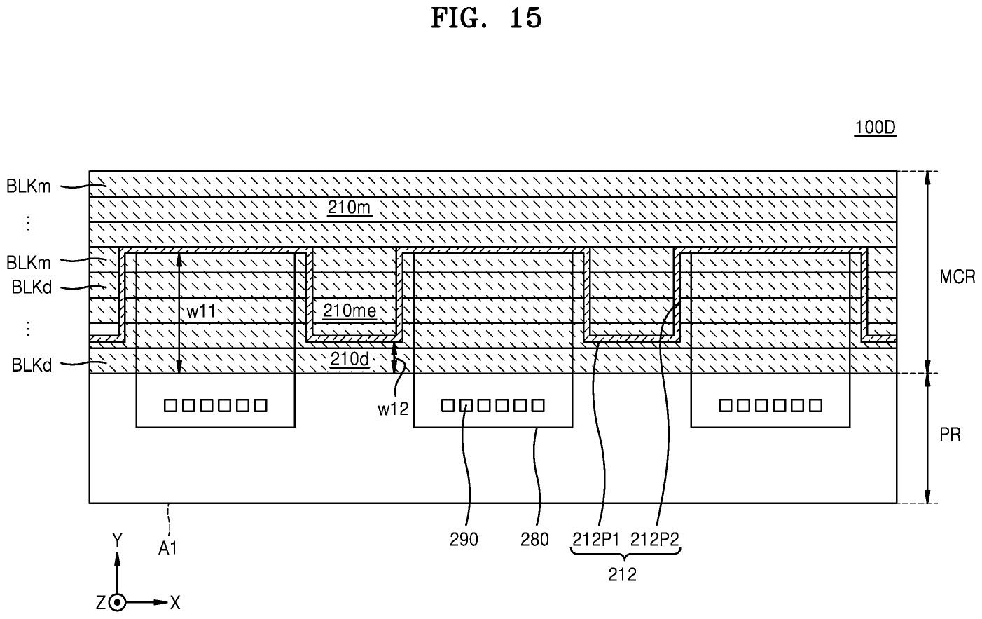

FIG. 15 is a top view illustrating a semiconductor device 100D according to an example embodiment of the present inventive concept.

Referring to FIG. 15, in a top view, the plurality of dummy blocks BLKd may be at one side of the plurality of main blocks BLKm, and the region of the input-output pad 280 may vertically overlap the plurality of dummy blocks BLKd. The common source isolation insulating layer 212 may be between the plurality of dummy blocks BLKd and the plurality of main blocks BLKm. The common source isolation insulating layer 212 may include a first part 212P1, which extends in the first horizontal direction X, and a second part 212P2, which extends in the second horizontal direction Y. In a top view, the first part 212P1 and the second part 212P2 may surround at least a portion of the input-output pad 280.

The dummy common source line region 210d may have a first width w11, which is in the second horizontal direction Y at a portion vertically overlapping the input-output pad 280, and have a second width w12, which is less than the first width w11, in the second horizontal direction Y at a portion (e.g., a region between two adjacent input-output pads 280) not vertically overlapping the input-output pad 280. A portion of the main common source line region 210m in the region between two adjacent input-output pads 280 may extend toward the dummy common source line region 210d, and a portion of the main common source line region 210m between the adjacent two input-output pads 280 may be referred to as an extension part 210me. Because the main common source line region 210m includes the extension part 210me, a common source line resistance may be reduced.

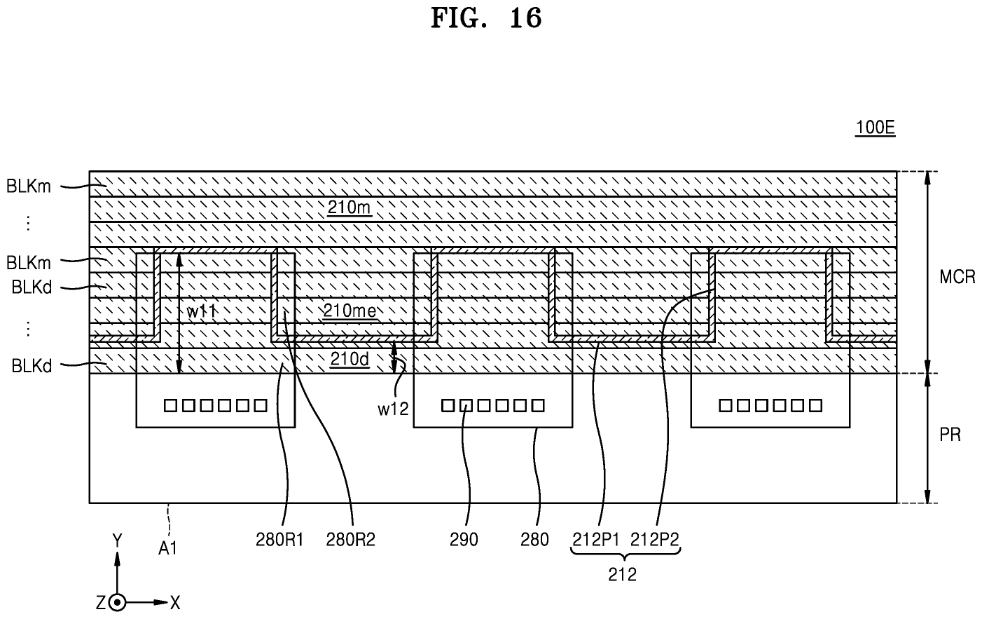

FIG. 16 is a top view illustrating a semiconductor device 100E according to an example embodiment of the present inventive concept.

Referring to FIG. 16, at least a portion of the input-output pad 280 may vertically overlap the extension part 210me of the main common source line region 210m. For example, a first region 280R1 of the input-output pad 280 may vertically overlap the dummy common source line region 210d, and a second region 280R2 of the input-output pad 280 may vertically overlap the extension part 210me of the main common source line region 210m.

According to some example embodiments of the present inventive concept, because the main common source line region 210m includes the extension part 210me, the common source line resistance may be reduced, and because the first region 280R1 of the input-output pad 280 vertically overlaps the dummy common source line region 210d, the input-output capacitance by the input-output pad 280 may be reduced, thereby increasing the input-output performance.

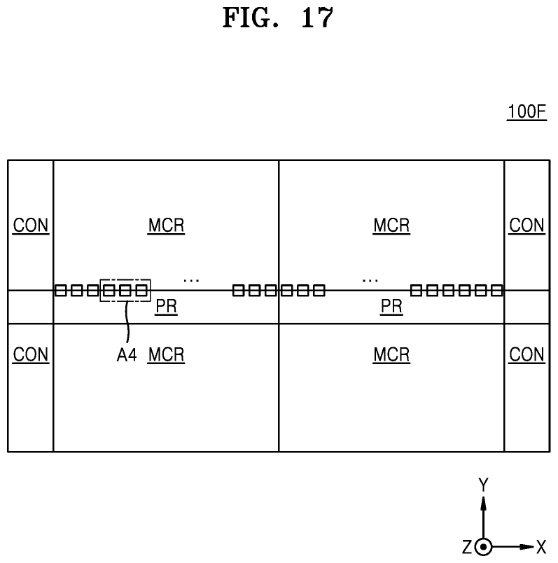

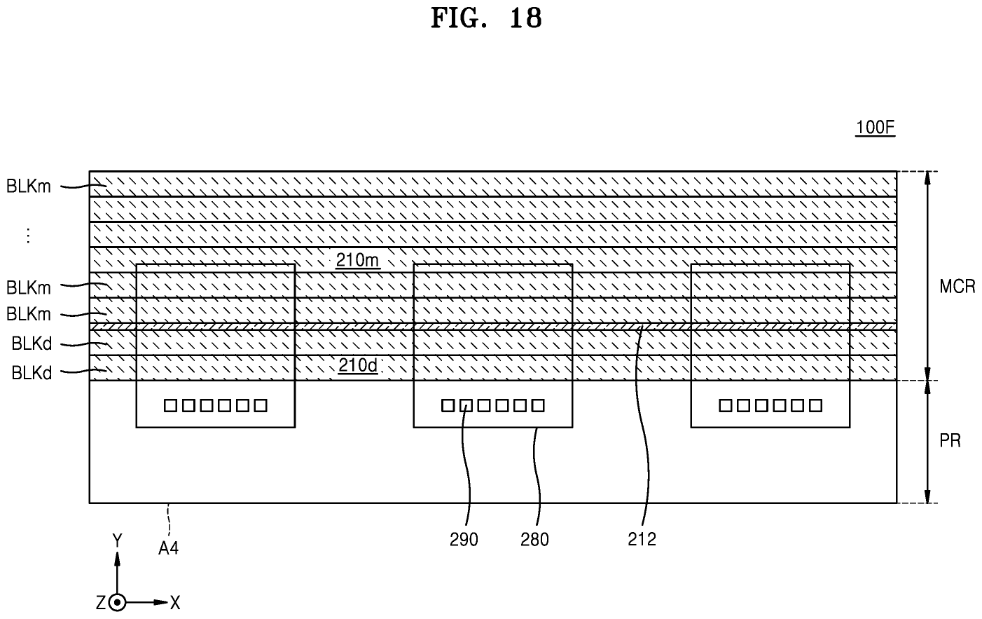

FIG. 17 is a top view illustrating a semiconductor device 100F according to an example embodiment of the present inventive concept, and FIG. 18 is a magnified view of part A4 of FIG. 17.

Referring to FIGS. 17 and 18, the semiconductor device 100F may have the pad region PR formed at a central part thereof, and the at least one dummy block BLKd may be in a region of the memory cell region MCR that is adjacent to the pad region PR.

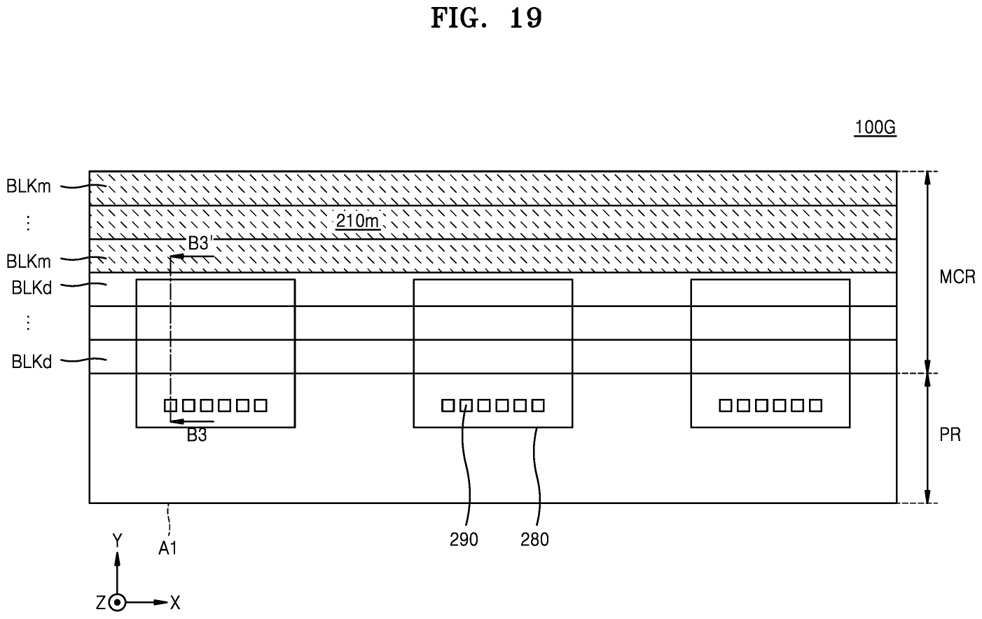

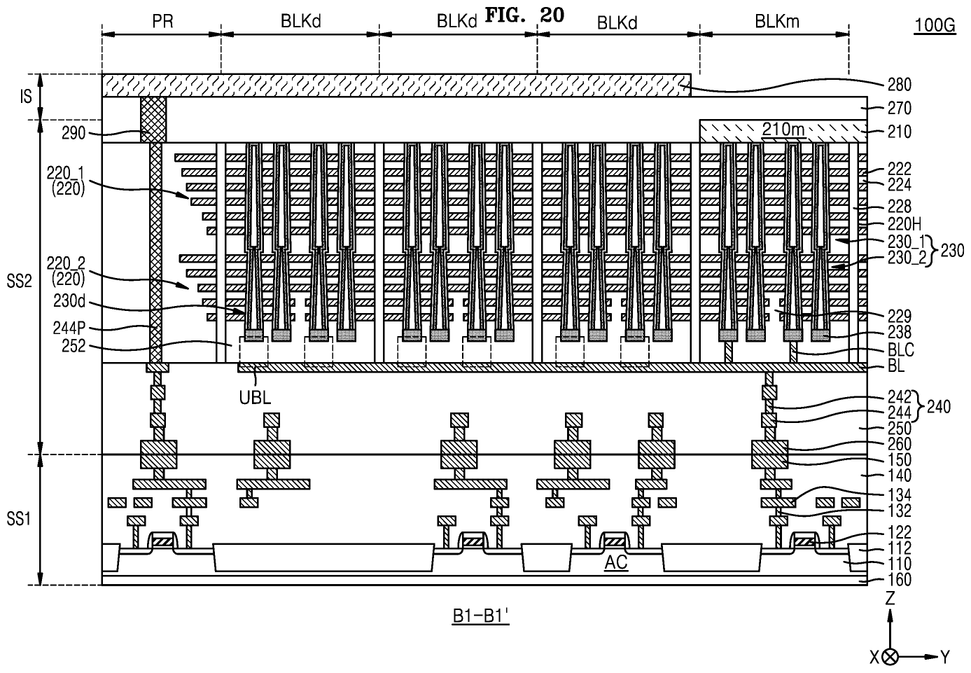

FIG. 19 is a top view illustrating a semiconductor device 100G according to example embodiment of the present inventive concept. FIG. 20 is a cross-sectional view taken along line B3-B3′ of FIG. 19.

Referring to FIGS. 19 and 20, the dummy common source line region 210d described with reference to FIGS. 3 to 8 may be omitted, and the at least one dummy block BLKd may vertically overlap the outer insulating layer 270. The outer insulating layer 270 may be between the input-output pad 280 and the at least one dummy block BLKd. In some example embodiments of the present inventive concept, by removing the dummy common source line region 210d and filling the outer insulating layer 270 in a portion from which the dummy common source line region 210d has been removed, the semiconductor device 100G described with reference to FIGS. 19 and 20 may be formed. According to some example embodiments of the present inventive concept, by disposing the outer insulating layer 270 between the input-output pad 280 and the at least one dummy block BLKd, the input-output capacitance by the input-output pad 280 may be reduced, thereby reducing the common source line noise or increasing the input-output performance.

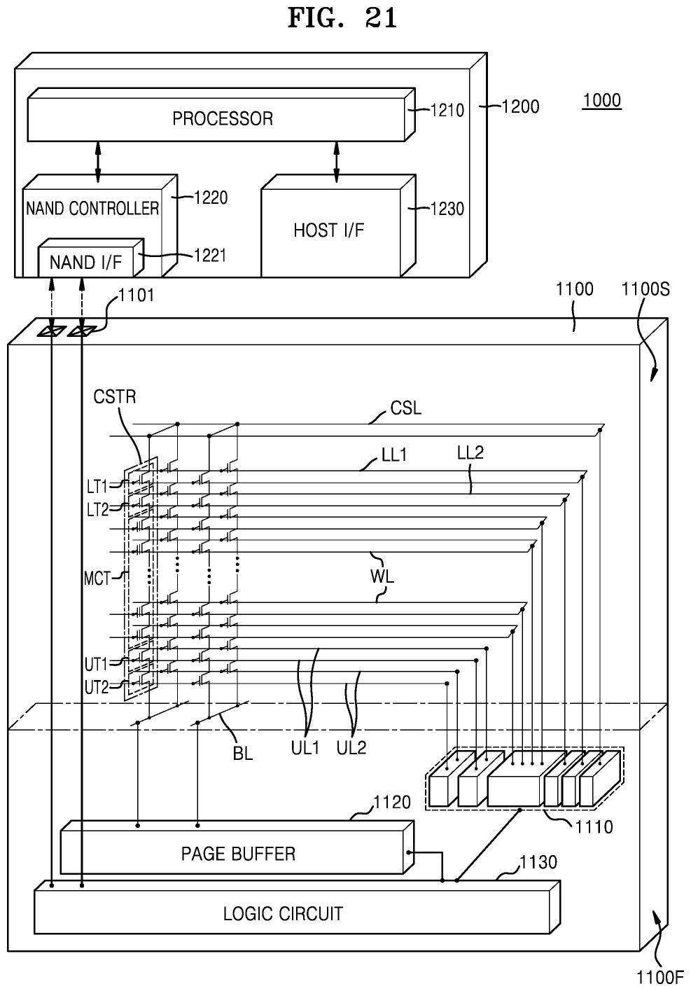

FIG. 21 is a block diagram of an electronic system 1000 including a semiconductor device, according to an example embodiment of the present inventive concept.

Referring to FIG. 21, the electronic system 1000 may include at least one semiconductor device 1100 and a memory controller 1200 electrically connected to the at least one semiconductor device 1100. The electronic system 1000 may be, for example, a solid state drive (SSD) device, a universal serial bus (USB) device, a computing system, a medical device, or a communication device including the at least one semiconductor device 1100.

A semiconductor device 1100 may be a nonvolatile semiconductor device, and for example, the semiconductor device 1100 may be a NAND flash semiconductor device including one of the semiconductor devices 10, 100, 100A, 100B, 100C, 100D, 100E, 100F, and 100G described with reference to FIGS. 1 to 20. The semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including the plurality of bit lines BL, the common source line CSL, the plurality of word lines WL, first and second string select lines UL1 and UL2, first and second ground select lines LL1 and LL2, and a plurality of memory cell strings CSTR disposed between the plurality of bit lines BL and the common source line CSL.

In the second structure 1100S, each of the plurality of memory cell strings CSTR may include ground select transistors LT1 and LT2, string select transistors UT1 and UT2, and a plurality of memory cell transistors MCT. The ground select transistors LT1 and LT2 may be adjacent to the common source line CSL, and the string select transistors UT1 and UT2 may be adjacent to a bit line BL. The plurality of memory cell transistors MCT may be between the ground select transistors LT1 and LT2 and the string select transistors UT1 and UT2. The number of ground select transistors LT1 and LT2 and the number of string select transistors UT1 and UT2 may be variously modified according to example embodiments of the present inventive concept.

In some embodiments of the present inventive concept, the first and second ground select lines LL1 and LL2 may be connected to gate electrodes of the ground select transistors LT1 and LT2, respectively. The plurality of word lines WL may be connected to gate electrodes of the plurality of memory cell transistors MCT, respectively. The first and second string select lines UL1 and UL2 may be connected to gate electrodes of the string select transistors UT1 and UT2, respectively.

The common source line CSL, the first and second ground select lines LL1 and LL2, the plurality of word lines WL, and the first and second string select lines UL1 and UL2 may be connected to the row decoder 1110. The plurality of bit lines BL may be electrically connected to the page buffer 1120.

The semiconductor device 1100 may communicate with the memory controller 1200 through input-output pads 1101 that are electrically connected to the logic circuit 1130. The input-output pads 1101 may be electrically connected to the logic circuit 1130.

The memory controller 1200 may include a processor 1210, a NAND controller 1220, and a host interface 1230. In some example embodiments of the present inventive concept, the electronic system 1000 may include a plurality of semiconductor devices 1100, and in this case, the memory controller 1200 may control the plurality of semiconductor devices 1100.

The processor 1210 may control a general operation of the electronic system 1000 including the memory controller 1200. The processor 1210 may operate according to certain firmware and control the NAND controller 1220 to access the semiconductor device 1100. The NAND controller 1220 may include a NAND interface 1221 configured to process communication with the semiconductor device 1100. Through the NAND interface 1221, a control command for controlling the semiconductor device 1100, data to be written on the plurality of memory cell transistors MCT in the semiconductor device 1100, data read from the plurality of memory cell transistors MCT in the semiconductor device 1100, and the like may be transferred. The host interface 1230 may provide a communication function between the electronic system 1000 and an external host. When a control command is received from the external host through the host interface 1230, the processor 1210 may control the semiconductor device 1100 in response to the control command.

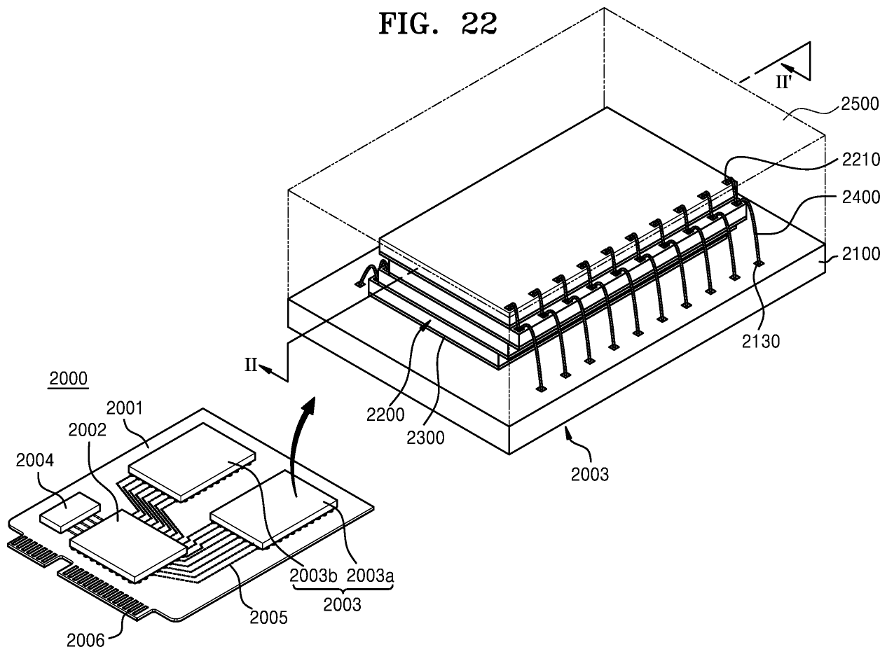

FIG. 22 is a perspective view schematically illustrating an electronic system 2000 including a semiconductor device, according to an example embodiment of the present inventive concept.

Referring to FIG. 22, the electronic system 2000 according to an example embodiment of the present inventive concept may include a main substrate 2001 and a memory controller 2002, a semiconductor package 2003, and dynamic random access memory (DRAM) 2004 mounted on the main substrate 2001. The semiconductor package 2003 and the DRAM 2004 may be connected to the memory controller 2002 through a plurality of wiring patterns 2005 formed on the main substrate 2001.

The main substrate 2001 may include a connector 2006 including a plurality of pins coupled to an external host. The number and the arrangement of pins in the connector 2006 may vary according to a communication interface between the electronic system 2000 and the external host. In some example embodiments of the present inventive concept, the electronic system 2000 may communicate with the external host according to any one of interfaces, such as a USB interface, a peripheral component interconnect express (PCI-Express) interface, a serial advanced technology attachment (SATA) interface, and an M-Phy interface for a universal flash storage (UFS). In some example embodiments of the present inventive concept, the electronic system 2000 may operate by power received from the external host through the connector 2006. The electronic system 2000 may further include a power management integrated circuit (PMIC) configured to distribute the power received from the external host to the memory controller 2002 and the semiconductor package 2003.

The memory controller 2002 may write or read data on or from the semiconductor package 2003 and increase an operating speed of the electronic system 2000.

The DRAM 2004 may be a buffer memory configured to mitigate a speed difference between the semiconductor package 2003, which is a data storage space, and the external host. The DRAM 2004 included in the electronic system 2000 may operate as a kind of cache memory and provide a space in which data is temporarily stored in a control operation on the semiconductor package 2003. When the DRAM 2004 is included in the electronic system 2000, the memory controller 2002 may further include a DRAM controller configured to control the DRAM 2004 in addition to a NAND controller configured to control the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, an adhesive layer 2300 beneath each of the plurality of semiconductor chips 2200, a plurality of connection structures 2400 electrically connecting the plurality of semiconductor chips 2200 to the package substrate 2100, and a molding layer 2500 covering the plurality of semiconductor chips 2200 and the plurality of connection structures 2400 on the package substrate 2100.

The package substrate 2100 may be a printed circuit board including a plurality of package upper pads 2130. Each of the plurality of semiconductor chips 2200 may include input-output pads 2210. The input-output pads 2210 may correspond to the input-output pads 1101 of FIG. 21. Each of the plurality of semiconductor chips 2200 may include at least one of the semiconductor devices 10, 100, 100A, 100B, 100C, 100D, 100E, 100F, and 100G described with reference to FIGS. 1 to 20.

In some example embodiments of the present inventive concept, the plurality of connection structures 2400 may be bonding wires electrically connecting the input-output pads 2210 to the plurality of package upper pads 2130. Therefore, in the first and second semiconductor packages 2003a and 2003b, the plurality of semiconductor chips 2200 may be electrically connected to each other by a bonding wire scheme and electrically connected to the plurality of package upper pads 2130 of the package substrate 2100. In some example embodiments of the present inventive concept, in the first and second semiconductor packages 2003a and 2003b, the plurality of semiconductor chips 2200 may be electrically connected to each other through a connection structure including through silicon vias (TSVs) instead of the plurality of connection structures 2400 of the bonding wire scheme.

In some example embodiments of the present inventive concept, the memory controller 2002 and the plurality of semiconductor chips 2200 may be included in one package. In some example embodiments of the present inventive concept, the memory controller 2002 and the plurality of semiconductor chips 2200 may be mounted on a separate interposer substrate other than the main substrate 2001, and the memory controller 2002 may be connected to the plurality of semiconductor chips 2200 through wirings formed on the interposer substrate.

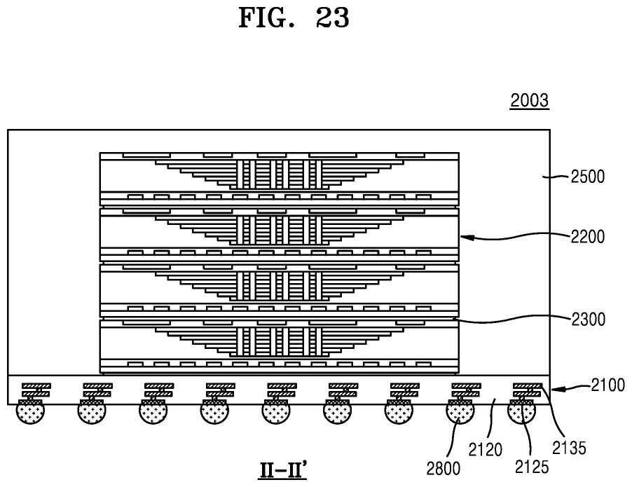

FIG. 23 is a cross-sectional view illustrating the semiconductor package 2003 according to an example embodiment of the present inventive concept. FIG. 23 is a cross-sectional view taken along line II-II′ of FIG. 22.

Referring to FIG. 23, in the semiconductor package 2003, the package substrate 2100 may be a printed circuit board. The package substrate 2100 may include a package substrate body part 2120, the plurality of package upper pads 2130 (see FIG. 22), which are on an upper surface of the package substrate body part 2120, a plurality of lower pads 2125 disposed on or exposed through a lower surface of the package substrate body part 2120, and a plurality of internal wirings 2135, which are disposed inside the package substrate body part 2120 to electrically connect the plurality of package upper pads 2130 (see FIG. 22) to the plurality of lower pads 2125. As shown in FIG. 22, the plurality of package upper pads 2130 may be electrically connected to the plurality of connection structures 2400. As shown in FIG. 23, the plurality of lower pads 2125 may be connected, through a plurality of conductive bumps 2800, to the plurality of wiring patterns 2005 on the main substrate 2001 of the electronic system 2000 shown in FIG. 22. Each of the plurality of semiconductor chips 2200 may include at least one of the semiconductor devices 10, 100, 100A, 100B, 100C, 100D, 100E, 100F, and 100G described with reference to FIGS. 1 to 20.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device comprising:
a first structure comprising a first substrate, a peripheral circuit disposed on the first substrate, a first insulating structure disposed on the peripheral circuit and the first substrate, and a first bonding pad disposed on the first insulating structure; and
a second structure comprising a common source plate, a cell stack, a second insulating structure, a second bonding pad, and an interconnect structure electrically connecting the cell stack to the second bonding pad, wherein the cell stack is disposed on the common source plate and comprises a plurality of gate electrodes and a plurality of channel structures connected to the common source plate by passing through the plurality of gate electrodes, wherein the second insulating structure is disposed on the cell stack and being in contact with the first insulating structure, wherein the second bonding pad is disposed on the second insulating structure and is in contact with the first bonding pad, wherein the cell stack comprises a plurality of cell blocks defined between a plurality of stack insulating layers extending in a first horizontal direction by passing through the cell stack, and wherein the plurality of cell blocks comprises a plurality of main blocks and at least one dummy block disposed at one side of the plurality of main blocks,
wherein the common source plate comprises a main common source line region and a dummy common source line region, wherein the main common source line region vertically overlaps the plurality of main blocks, wherein the dummy common source line region is separated from the main common source line region and vertically overlaps the at least one dummy block by being electrically isolated from the at least one dummy block.

2. The semiconductor device of claim 1, wherein the dummy common source line region is configured to float when a common source voltage is applied to the main common source line region.

3. The semiconductor device of claim 1, wherein the second structure further comprises a bit line electrically connected to a first channel structure included in the plurality of main blocks among the plurality of channel structures and electrically isolated from a second channel structure included in the at least one dummy block among the plurality of channel structures.

4. The semiconductor device of claim 3, wherein the bit line extends in a second horizontal direction, which is substantially perpendicular to the first horizontal direction, to vertically overlap both the first channel structure and the second channel structure, wherein a first bit line contact is disposed between the bit line and the first channel structure to electrically connect the bit line to the first channel structure, and no bit line contact is disposed between the bit line and the second channel structure.

5. The semiconductor device of claim 3, wherein the bit line extends in a second horizontal direction, which is substantially perpendicular to the first horizontal direction, to vertically overlap the first channel structure and not to vertically overlap the second channel structure, and wherein a first bit line contact is disposed between the bit line and the first channel structure to electrically connect the bit line to the first channel structure.

6. The semiconductor device of claim 1, wherein the second structure further comprises a common source isolation insulating layer disposed between the main common source line region and the dummy common source line region of the common source plate.

7. The semiconductor device of claim 6, wherein the common source isolation insulating layer extends in the first horizontal direction, and the dummy common source line region has a rectangular shape.

8. The semiconductor device of claim 1, further comprising a connection structure comprising an outer insulating layer and an input-output pad, wherein the outer insulating layer covers the common source plate on the second structure, wherein the input-output pad is disposed on the outer insulating layer and is electrically connected to the interconnect structure, and wherein at least a portion of the input-output pad vertically overlaps at least a portion of the at least one dummy block.

9. The semiconductor device of claim 8, wherein a first part of the input-output pad vertically overlaps the dummy common source line region, and a second part of the input-output pad vertically overlaps the main common source line region.

10. The semiconductor device of claim 8, wherein the input-output pad vertically overlaps the dummy common source line region.

11. The semiconductor device of claim 8, wherein the input-output pad comprises:
a first input-output pad vertically overlapping the at least one dummy block; and
a second input-output pad separated from the first input-output pad in the first horizontal direction and vertically overlapping the at least one dummy block,
wherein the dummy common source line region has a first width in a second horizontal direction, which is substantially perpendicular to the first horizontal direction, at a first position where the dummy common source line region vertically overlaps the first input-output pad, and the dummy common source line region has a second width, which is less than the first width, in the second horizontal direction at a second position where the dummy common source line region vertically overlaps a region between the first input-output pad and the second input-output pad.

12. The semiconductor device of claim 11, wherein the dummy common source line region vertically overlaps the first input-output pad and the second input-output pad.

13. A semiconductor device comprising:
a first structure comprising a first substrate, a peripheral circuit disposed on the first substrate, a first insulating structure disposed on the peripheral circuit and the first substrate, and a first bonding pad disposed on the first insulating structure; and
a second structure comprising a common source plate, a cell stack, a second insulating structure, and a second bonding pad disposed on the second insulating structure and being in contact with the first bonding pad, wherein the cell stack is disposed on the common source plate and comprises a plurality of gate electrodes and a plurality of channel structures passing through the plurality of gate electrodes, wherein the second insulating structure is disposed on the cell stack and is in contact with the first insulating structure, wherein the cell stack comprises a main block and a dummy block disposed at one side of the main block,
wherein the common source plate comprises:
a main common source line region connected to a first channel structure in the main block among the plurality of channel structures; and
a dummy common source line region connected to a second channel structure in the dummy block among the plurality of channel structures and separated from the main common source line region,
wherein the dummy common source line region is configured to float when a common source voltage is applied to the main common source line region.

14. The semiconductor device of claim 13, wherein the cell stack further comprises a stack insulating layer extending in a first horizontal direction between the main block and the dummy block by passing through the cell stack, and the second structure further comprises a bit line extending in a second horizontal direction, which is substantially perpendicular to the first horizontal direction, and electrically connected to the first channel structure, wherein the bit line is electrically isolated from the second channel structure.

15. The semiconductor device of claim 14, wherein the bit line extends in the second horizontal direction to vertically overlap both the first channel structure and the second channel structure, wherein a first bit line contact is disposed between the bit line and the first channel structure to electrically connect the bit line to the first channel structure, and no bit line contact is disposed between the bit line and the second channel structure.

16. The semiconductor device of claim 14, wherein the bit line extends in the second horizontal direction to vertically overlap the first channel structure and not to vertically overlap the second channel structure, and wherein a first bit line contact is disposed between the bit line and the first channel structure.

17. The semiconductor device of claim 13, further comprising:
an outer insulating layer covering the common source plate and disposed on the second structure; and
an input-output pad disposed on the outer insulating layer,
wherein at least a portion of the input-output pad vertically overlaps at least a portion of the dummy block.

18. The semiconductor device of claim 17, wherein the second structure further comprises a common source isolation insulating layer disposed between the main common source line region and the dummy common source line region, and wherein the common source isolation insulating layer is connected to the outer insulating layer.

19. An electronic system comprising:
a main substrate;
a semiconductor device disposed on the main substrate; and
a controller electrically connected to the semiconductor device on the main substrate,
wherein the semiconductor device comprises:
a first structure comprising a first substrate, a peripheral circuit disposed on the first substrate, a first insulating structure disposed on the peripheral circuit and the first substrate, and a first bonding pad disposed on the first insulating structure;
a second structure comprising a common source plate, a cell stack, a second insulating structure, a second bonding pad, and an interconnect structure electrically connecting the cell stack to the second bonding pad, wherein the cell stack is disposed on the common source plate and comprises a plurality of gate electrodes and a plurality of channel structures connected to the common source plate by passing through the plurality of gate electrodes, wherein the second insulating structure is disposed on the cell stack and is in contact with the first insulating structure, wherein the second bonding pad is disposed on the second insulating structure and is in contact with the first bonding pad, wherein the cell stack comprises a plurality of cell blocks defined between a plurality of stack insulating layers extending in a first horizontal direction by passing through the cell stack, and the plurality of cell blocks comprises a plurality of main blocks and at least one dummy block disposed at one side of the plurality of main blocks; and
a connection structure comprising an outer insulating layer and an input-output pad, wherein the connection structure covers the common source plate and is disposed on the second structure, and wherein the input-output pad is disposed on the outer insulating layer and is electrically connected to the interconnect structure, wherein at least a portion of the input-output pad vertically overlaps at least a portion of the at least one dummy block,
wherein the common source plate comprises a main common source line region and a dummy common source line region, wherein the main common source line region vertically overlaps the plurality of main blocks, wherein the dummy common source line region is separated from the main common source line region and vertically overlaps the at least one dummy block by being electrically isolated from the at least one dummy block.

20. The electronic system of claim 19, wherein the second structure further comprises:
a bit line electrically connected to a first channel structure included in a main block, of the plurality of main blocks, among the plurality of channel structures and electrically isolated from a second channel structure included in the at least one dummy block among the plurality of channel structures; and
a common source isolation insulating layer disposed between the main common source line region and the dummy common source line region of the common source plate, and
wherein the dummy common source line region is configured to float when a common source voltage is applied to the main common source line region.
